(19) United States
(12) Patent Application Publication
(10) Pub. No.: US 2003/0076252 A1
(43) Pub. Date: Apr. 24, 2003

(54) Version identifying device with the A/D conversion function and its method

(76) Inventors: Jeffrey Lo, Taipei (TW); Roger Tsai, Taipei (TW); Jeffrey Hu, Taipei (TW)

Correspondence Address: BIRCH STEWART KOLASCH & BIRCH, PO BOX 747, FALLS CHURCH, VA, 22040-0747, US

(21) Appl. No.: 09/982,012

(22) Filed: Oct. 19, 2001

(51) Int. Cl. H03M 1/12

(52) U.S. Cl. 341/155

(57) ABSTRACT

A version identification device with the A/D conversion function and its method. The invention includes a voltage dividing unit and a processing device. The voltage dividing unit is installed on an electronic device. The version of the electronic device is converted into analog signals using the voltage dividing unit. The analog signal is then sent to the processing device to be converted into a digital signal. The digital signal is then computed and identified to achieve the goal of identifying the version of the electronic device.

### BACKGROUND OF THE INVENTION

1. Field of Invention

The invention pertains to a version identification device and, in particular, to a version identification device with the A/D conversion function that can be used to identify the electronic device version.

2. Related Art

Due to the prosperous development in the electronic industry, there are more and more innovative and improved functions on electronic devices. However, the development of any electronic device always has several modifications from the beginning to the final product. Therefore, each electronic device has many different versions in functions and designs.

As sometimes many versions of an electronic device differ only in partial modifications, one cannot identify their versions from their appearance. Thus, version identification become important and version identification devices are invented. According to conventional version identification methods, the version or model of an electronic device is attached or printed on the shell of the device. Nevertheless, due to the aging or erosion of the attached or printed information, the version or model tag on the shell may become unidentifiable. This will cause inconvenience for the user or maintenance staff.

To solve the above-mentioned problem, most new version identification devices are installed within the electronic device and output digital signals through the I/O (Input/Output) pins of the electronic device to identify its version. Although this method can circumvent the above-mentioned erosion or aging problem, as more and more versions of the electronic device come out the I/O pins have to be increased too. This also makes the design difficult.

### SUMMARY OF THE INVENTION

In view of the foregoing, it is an object of the invention to provide a version identification device with the A/D conversion function that can achieve the goal of identifying the electronic device version and to make the circuit design easy. The device includes a voltage dividing unit and a processing device. The voltage dividing unit is installed in the electronic device. The version of the electronic device is converted by the voltage dividing unit into an analog signal which is then output through a single pin. The processing device receives the analog signal and converts it into a digital signal. The digital signal is then computed and identified to obtain the version of the electronic device. The invention also discloses the corresponding method.

### BRIEF DESCRIPTION OF THE DRAWINGS

The present invention will become more fully understood from the detailed description given hereinbelow illustration only, and thus are not limitative of the present invention, and wherein:

FIG. 1 is a system block diagram of the disclosed version identification device with the A/D conversion function; and

FIG. 2 is a flowchart of the disclosed version identification method with the A/D conversion function.

### DETAILED DESCRIPTION OF THE INVENTION

The version identification device with the A/D conversion function of the invention can convert the electronic device version into an analog signal output and then convert it into a digital signal for identification.

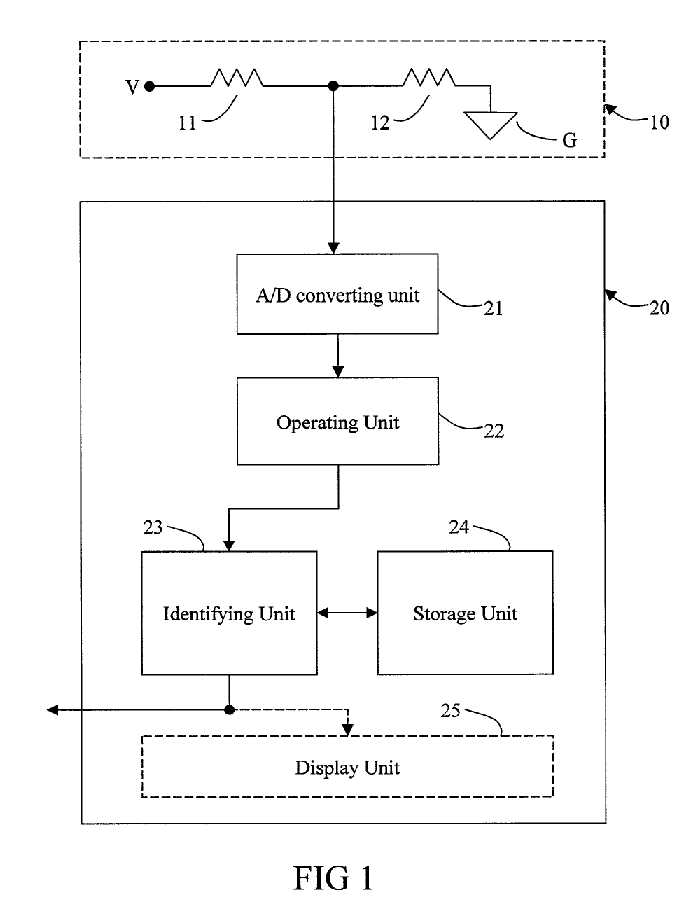

With reference to FIG. 1, the disclosed version identification device with the A/D conversion function includes a voltage dividing unit 10 and a processing device 20. The voltage dividing unit 10 is installed in the electronic device to generate an analog signal. The analog signal is then sent to an output terminal. The processing device 20 is connected to the voltage dividing unit 10 to receive the analog signal. The processing device 20 then converts the received analog signal into a digital signal. The digital signal is then computed and compared with the version information stored in the processing device 20.

The voltage dividing unit 10 extracts the analog signal according to the partial voltage principle. It further includes a first load 11 and a second load 12. The first load 11 and the second load 12 can be resistors. A first end of the first load 11 couples to a voltage source V to produce a load voltage. A first end of the second load 12 couples to a second end of the first load 11. A second end of the second load 12 couples to the ground G to produce another load voltage. The analog signal is extracted from the coupling point of the second load 12 and the first load 11.

The processing device 20 contains an A/D converting unit 21, an operating unit 22, an identifying unit 23 and a storage unit 24. The A/D converting unit 21 connects to the voltage dividing unit 10 to receives the analog signal produced by the voltage dividing unit 10 and converts it into a digital signal. The operating unit 22 connects to the A/D converting unit 21. It receives the digital signal and performs a shift operation on the digital signal to obtain an effect bit for identification. The storage unit 24 stores default version information for the comparison done by the identifying unit 23. The identifying unit 23 has a first input terminal, a second input terminal and an output terminal. The first input terminal connects to the operating unit 22 to receive the digital signal. The second input terminal connects to the storage unit 24 to receive the default version information. The identifying unit 23 compares the digital signal and the default version information and, after completing the comparison, produces a driving signal that is transmitted to the output terminal of the identifying unit 23.

The above-mentioned version identification device with the A/D conversion function can be further installed with a display unit 25. The display unit 25 connects to the identifying unit 23 to receive the driving signal from the identifying unit 23 and uses the driving signal to display the version of the electronic device. The first load 11 and the second load 12 of the invention can be designed to have different resistances so as to provide analog signals with different potentials, thereby achieving the goal of version identification.

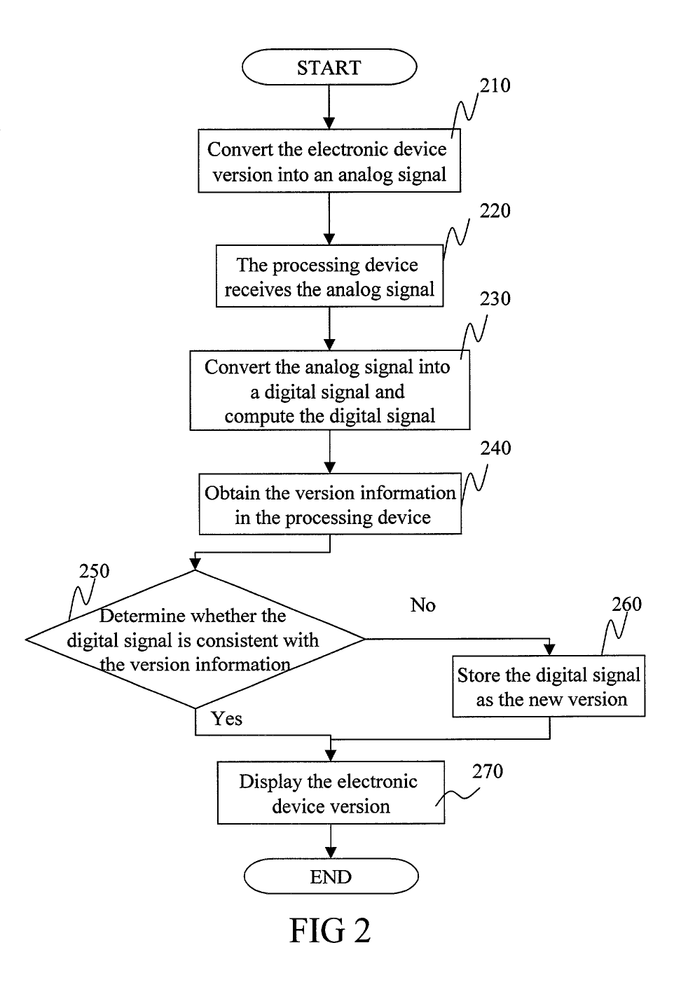

With reference to FIG. 2, where the disclosed method is shown in a flowchart, the version data of an electronic device is converted into an analog signal by the voltage dividing unit 10 (step 210). The signal is then sent to a processing device 20. An A/D converting unit 21 of the processing device 20 receives the analog signal (step 220) and converts it into a digital signal. An operating unit 22 performs a shift operation on the digital signal (step 230). The version information is read out from the storage unit 24 of the processing device 20 (step 240). The digital signal is then compared with the version information stored in the processing device 20. When the digital signal and the version information are consistent (step 250), the display unit 25 displays the version of the electronic device (step 270). If they are inconsistent, then the digital signal is stored in the storage unit 24 of the processing device 20 as a new version (step 260). The display unit 25 then displays the electronic device as a new version (step 270).

From the above description, the disclosed device and method can avoid the trouble with any unidentifiable serial number on the shell of an electronic device. Furthermore, the invention uses an analog method to output version information. The advantage of this method is that the number of I/O pins on the electronic device for version identification can be decreased.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A version identification device with the A/D conversion function for identifying the version of an electronic device, which is comprised of:
a voltage dividing unit, which is installed in the electronic device to generate and output an analog signal to an output terminal; and
a processing device, which connects to the voltage dividing unit to receive the analog signal and to convert it into a digital signal, the digital signal being processed and compared with version information.

2. The version identification device of claim 1, wherein the voltage dividing unit further comprises:
a first load, which has a first end coupling to a voltage source to produce a load voltage; and
a second load, which has a first end coupling to a second end of the first load and a second end coupling to a ground to produce a load voltage;
wherein the analog signal is extracted from the coupling point between the second load and the first load.

3. The version identification device of claim 1, wherein the processing device further comprises:
a storage unit, which stores at least one version data as the version information;
an A/D converting unit, which couples to the voltage dividing unit to convert the analog signal into a digital signal;
an operating unit, which couples to the A/D converting unit to receive the digital signal and to perform a shift operation on the digital signal; and
an identifying unit, which has a first input terminal coupling to the operating unit to receive the digital signal and a second input terminal coupling to the storage unit to receive the version information, compares the digital signal with the version information and, after completing the comparison, produces and sends a driving signal to its output terminal.

4. The version identification device of claim 1 further comprising a display unit coupling to the identifying unit to receive the driving signal and thereby display the version of the electronic device.

5. The version identification device of claim 1, wherein the electronic device is a mobile phone.

6. The version identification device of claim 1, wherein the electronic device is a PDA (Personal Digital Assistant).

7. The version identification device of claim 1, wherein the electronic device is a laptop computer.

8. The version identification device of claim 2, wherein the first load is a resistor.

9. The version identification device of claim 2, wherein the second load is a resistor.

10. A method for identifying the version of an electronic device, which comprises the steps of:
converting the version data of an electronic device into an analog signal;
using a processing device to receive the analog signal;
converting the analog signal into a digital signal and performing an operation on it;
reading in the version information in the processing device;
comparing the digital signal with the version information in the processing device; and
displaying the version of the electronic device.

11. The method of claim 10, wherein the electronic device is a mobile phone.

12. The method of claim 10, wherein the electronic device is a PDA.

13. The method of claim 10, wherein the electronic device is a laptop computer.
